(19) United States
(12) Patent Application Publication
(10) Pub. No.: US 2025/0279355 A1
(43) Pub. Date: Sep. 4, 2025

(54) DATA AND POWER ISOLATION WITH DOUBLE ISOLATION BARRIER

(71) Applicant: TEXAS INSTRUMENTS INCORPORATED, Dallas, TX (US)

(72) Inventors: Nicola Bertoni, Freising (DE); Giacomo Calabrese, Freising (DE)

(21) Appl. No.: 18/592,460

(22) Filed: Feb. 29, 2024

(51) Int. Cl. H01L 23/522; H01L 23/00; H01L 23/528

(52) U.S. Cl. CPC H01L 23/5227; H01L 23/5286; H01L 24/05; H01L 24/29; H01L 2224/05009; H01L 2224/05025; H01L 2224/29009; H01L 2224/29025; H01L 2924/182; H01L 2924/30107

(57) ABSTRACT

A packaged integrated circuit (IC) including a package substrate. The package substrate includes pins; a first metal layer on the pins; a second metal layer on the first metal layer; vias on the second metal layer; an insulation material covering the pins, the first metal layer, the second metal layer, and the vias, and exposing surfaces of the pins and the vias. The packaged IC further includes a semiconductor die on the package substrate, the semiconductor die having a surface opposing the second metal layer; metal posts coupled between the semiconductor die and the exposed surfaces of the vias; and a mold compound covering the semiconductor die and the metal posts, in which the surface is separated from the second metal layer by the insulation material and the mold compound.

### BACKGROUND

Isolation is often desirable for interconnecting electrical systems to exchange data or power between the systems. For example, two systems may be powered by different supply sources that do not share a common ground connection. The two systems may be electrically isolated to prevent current and voltages in one system from negatively impacting the other system, for instance by damaging or interfering with the operation of one or more components of the other system. In some applications that use isolation circuits, challenges may arise with respect to size of the isolation circuit, maintaining voltage isolation across different voltage domains, interconnection parasitics, and isolation circuit efficiency.

### SUMMARY

Described is a packaged integrated circuit comprising a packaged integrated circuit (IC) comprising a package substrate including a first metal layer, a second metal layer on the first metal layer, and a third metal layer on the second metal layer. In at least one example, the package substrate includes first vias coupled between the first metal layer and the second metal layer. In at least one example, the package substrate includes second vias coupled between the second metal layer and the third metal layer, and third vias on the third metal layer, in which the first metal layer includes pins. In at least one example, the second metal layer includes a first winding of a transformer, and the third metal layer includes a second winding of the transformer. In at least one example, the package substrate includes an insulation material covering the first, second, and third metal layers and the first, second, and third vias, and exposing surfaces of the pins and the third vias. In at least one example, the packaged IC includes a first semiconductor die on the package substrate. In at least one example, the packaged IC includes a second semiconductor die on the package substrate. In at least one example, first metal posts are coupled between the first semiconductor die and the exposed surfaces of a first subset of the third vias. In at least one example, second metal posts are coupled between the second semiconductor die and the exposed surfaces of a second subset of the third vias. In at least one example, the packaged IC includes a mold compound covering the first and second semiconductor dies and the first and second metal posts.

Described herein is another a packaged IC including a package substrate including pins; a first metal layer on the pins; a second metal layer on the first metal layer; vias on the second metal layer; and an insulation material covering the pins, the first metal layer, the second metal layer, and the vias, and exposing surfaces of the pins and the vias. In at least one example, the packaged IC includes a semiconductor die on the package substrate, the semiconductor die having a surface opposing the second metal layer. In at least one example, the packaged IC includes metal posts coupled between the semiconductor die and the exposed surfaces of the vias. In at least one example, the packaged IC includes a mold compound covering the semiconductor die and the metal posts, in which the surface is separated from the second metal layer by the insulation material and the mold compound.

Described is a method of fabricating a packaged integrated circuit, comprising flipping a package substrate having a first metal layer, a second metal layer below the first metal layer, and a third metal layer below the second metal layer. In at least one example, the package substrate further includes first vias coupled between the first metal layer and the second metal layer. In at least one example, the package substrate includes second vias coupled between the second metal layer and the third metal layer. In at least one example, the package substrate includes third vias below the third metal layer, in which the first metal layers include pins. In at least one example, the method comprises forming first metal posts on exposed surfaces of a first subset of the third vias. In at least one example, the method comprises forming second metal posts on exposed surfaces of a second subset of the third vias. In at least one example, the method further comprises mounting a first semiconductor die on the first metal posts. In at least one example, the method further comprises mounting a second semiconductor die on the second metal posts. In at least one example, the method further comprises covering the first and second semiconductor dies and the first and second metal posts with a mold compound.

### BRIEF DESCRIPTION OF THE DRAWINGS

The examples will be understood more fully from the detailed description given below and from the accompanying drawings, which, however, should not be taken to limit the disclosure to the specific examples, but are for explanation and understanding only.

FIG. 1A is a schematic depicting an example packaged integrated circuit (IC) having an integrated isolation circuit comprising a power transformer, in accordance with at least one example.

FIG. 1B is a schematic depicting an example packaged IC having an integrated isolation circuit comprising a power transformer and one or more data transformers, in accordance with at least one example.

FIG. 2 is a schematic showing a DC-DC converter formed on two semiconductor dies coupled by a power transformer, in accordance with at least one example.

FIG. 3 is a schematic illustrating a cross section of a packaged IC with at least two barrier layers adjacent to windings in an isolation barrier, in accordance with at least one example.

FIG. 4 is a schematic illustrating an isometric view of packaged IC having a power transformer, in accordance with at least one example.

FIG. 5 is a schematic illustrating an isometric view of packaged IC having the power transformer and a data transformer, in accordance with at least one example.

FIG. 6 is a schematic illustrating a top view of a power transformer and two data transformers, in accordance with at least one example.

FIGS. 7A-B are schematics illustrating isometric views of the data transformers, in accordance with some examples.

FIG. 8 is a flowchart of a method of forming the packaged IC, in accordance with at least one example.

### DETAILED DESCRIPTION OF EXAMPLE EMBODIMENTS

Described herein is a packaged integrated circuit (IC) that comprises two semiconductor dies that are coupled to an isolation circuit (e.g., an isolation barrier) which is integrated within a package substrate. In at least one example, the package substrate includes two metal layers. In at least one example, the package substrate includes three metal layers. The semiconductor dies include a first semiconductor die with a first power circuit and a second semiconductor die with a second power circuit, where the first semiconductor die is coupled to the second semiconductor die via a power transformer which is part of the isolation circuit.

The power transformer comprises two windings in two different layers. In at least one example, a region exists between surfaces of the first and second semiconductor dies and a primary winding (e.g., top winding) of the power transformer, where the surfaces face the primary winding of the power transformer. In at least one example, the region forms an additional isolation barrier which comprises part of a mold compound that surrounds the first and second semiconductor dies and the package substrate. In at least one example, an isolation barrier region exists between the primary winding (e.g., top winding) and a secondary winding (e.g., bottom winding) of the two windings of the power transformer.

In at least one example, the first semiconductor die and the second semiconductor die include data circuits that are coupled via a data transformer (or a set of data transformers), which is also part of the isolation circuit. The data circuits provide bidirectional signaling, in accordance with at least one example. In at least one example, the data transformer or the set of data transformers are positioned within openings of windings of the power transformer and within the footprint of the power transformers. In at least one example, semiconductor dies are flip-chip dies that allow connection with the transformer(s) below it with reduced interconnection.

In at least one example, the data circuits are used for sending and receiving signals via one or more data channels between the first and second power semiconductor dies to realize a DC-DC converter. In at least one example, the data circuits can be used for other functions such as telemetry, data signaling, buffering of analog input signals for an analog-to-digital converter, buffering of digital input signals for a digital-to-analog converter, etc. In at least one example, the data transformer can be multiplexed between sending internal data (e.g., feedback data from the secondary side back to the primary side within the packaged IC) and external data (e.g., external to the packaged IC). In at least one example, an additional semiconductor die is positioned on the package substrate, where the additional semiconductor die receives power from the second power semiconductor die, and sends and receives data to and from the data circuit of the second semiconductor die. The additional semiconductor die can be any application specific semiconductor die or a general microcontroller.

By integrating the semiconductor dies for power regulation and data transfer with the isolation circuit, which is integrated in the package substrate, overall size of the packaged IC is reduced. The flip-chip assembly for the semiconductor dies allows for tighter parameter control which reduces the size or area of the packaged IC, which can result in shorter and/or fewer interconnect routing, closer connections, smaller parasitic capacitances, resistances, and/or inductances, etc. Flip-chip dies can overlap the transformers, which can reduce parasitic capacitances, resistances, and/or inductances involved in connecting the transformers to the flip-chip dies. Routing over the package substrate (e.g., using wire bonding) can be eliminated or at least reduced as most signal and power routings can be in the package substrate. The reduced parasitic capacitances, resistances, and/or inductances involved in connecting the transformers of the isolation circuit with respect to a bonded assembly, allow tailoring of the power and data channels down to the application needs and achieve higher power transfer efficiency. Reduced parasitic capacitances, resistances, and/or inductances increase transformer coupling that also translates to higher power transfer efficiency. The isolation barrier between the top winding of the power transformer allows for enough clearance and isolation between the top winding and the first and second semiconductor dies that two very different power domains can be used for the first and second semiconductor dies. Because of the reduced parasitic capacitances, resistances, and/or inductances, ringing in the power supply can also be reduced, which can improve reliability and improve noise immunity and bandwidth of data transmission.

Moreover, by placing the transformers of the isolation circuit in the package substrate, which can be much thicker than the transformer windings, the vertical separation between the transformer windings and the semiconductor die can be increased, at least compared with the case where the transformer windings (or other isolation circuit) formed in the metallization layer over the semiconductor die. Such arrangements can reduce the parasitic capacitance between the transformer windings and the semiconductor die, which can provide connection to ground. The reduced parasitic capacitance can improve the quality factor (QF) of the transformer. The increased vertical separation can also reduce the eddy current in the semiconductor die caused by the magnetic field generated by the transformer, which can reduce loss and further improve power transfer efficiency. Further, as explained below, the transformer can also provide improved common mode transient immunity and improved matching for differential signals.

The flexibility in the routing capability of the package substrate also improves the connectivity and signal integrity of the serviced application specific IC. The packaged IC of some examples integrate power and bidirectional data communication with minimized/reduced crosstalk, so that they operate independently, which makes the use of the isolated co-packaged device more flexible. In at least one example, the package substrate comprising two metal layers improves efficiency for power transformers using thicker metal (e.g., copper) traces. Since the semiconductor dies are over the package substrate, the transformers in the package substrate can be distanced from the semiconductor dies, which can reduce the Eddy current loss in the semiconductor substrates induced by the transformers. Accordingly, compared with transformers that are integrated in the silicon metallization layers, transformers in the package substrate can have higher QFs. Embedding the data transformers in the substrate also allows for high frequency signal communication between data integrated circuits. Routing signal and power through a package substrate having two metal layers reduces interconnect congestion on top of the substrate, which allows for smaller packaged integrated circuit as semiconductor dies in the packaged integrated circuit are placed closer to one another.

In the drawings, like reference numerals refer to like elements throughout, and the various features are not necessarily drawn to scale. Here, the same reference numbers or other reference designators are used in the drawings to designate the same or similar (either by function and/or structure) features.

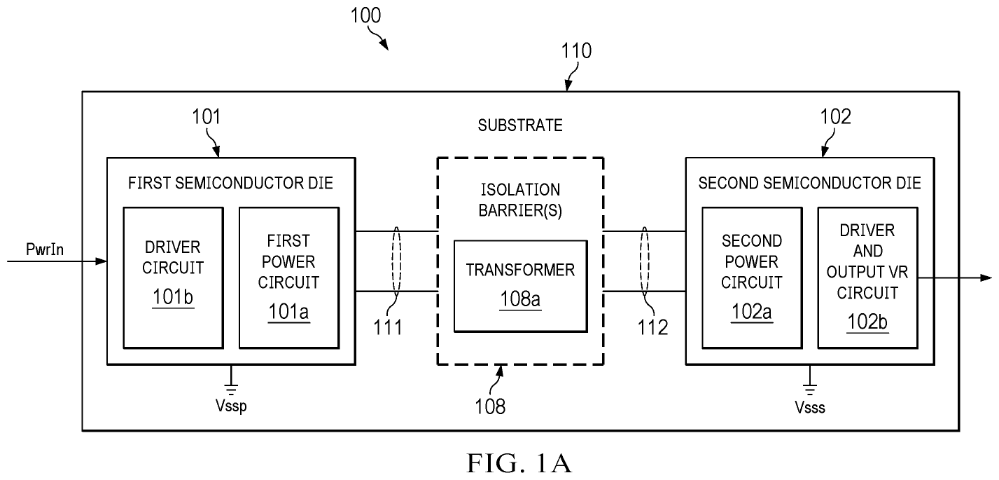

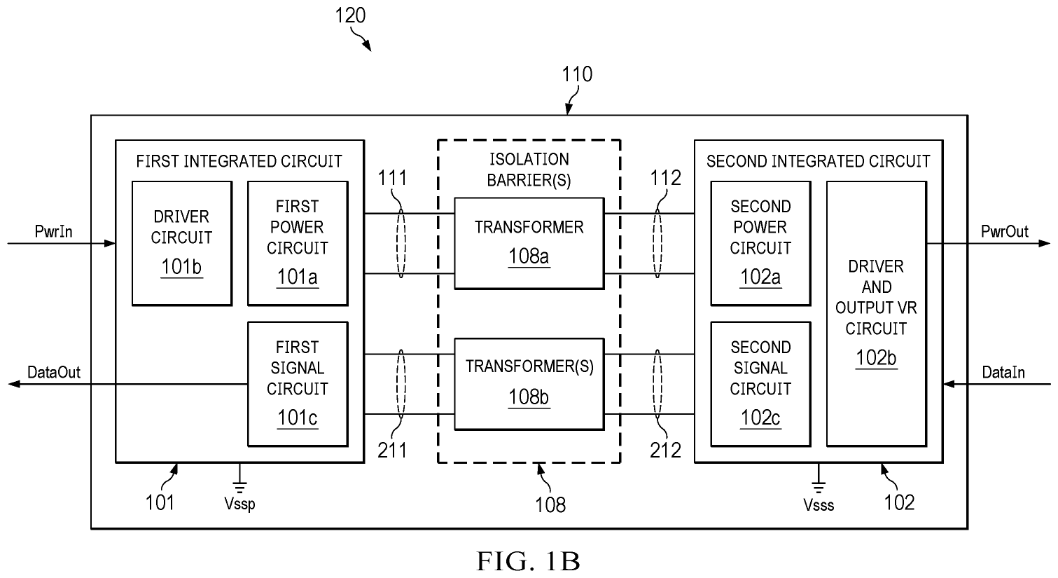

FIG. 1A is a schematic depicting an example packaged integrated circuit (IC) having an integrated isolation circuit comprising a power transformer, in accordance with at least one example. In at least one example, packaged IC 100 includes a first semiconductor die 101, and a second semiconductor die 102, an integrated isolation circuit 108, and a package substrate 110, such as a lead frame. Semiconductor dies 101 and 102 are mounted to package substrate 110, which can support first and second semiconductor dies 101 and 102 as a circuit support structure.

In at least one example, integrated isolation circuit 108 is integrated, formed, or embedded into layers (not shown) of package substrate 110, as indicated by dashed lines. In at least one example, package substrate 110 includes contact pads (not shown) and may include metallic interconnects 111 and 112 (four shown) to allow interconnectivity between first and second semiconductor dies 101 and 102 and integrated isolation circuit 108. Each interconnect 111 and 112 may represent power and/or data channels with one or more electrical traces and/or vias.

In at least one example, integrated isolation circuit 108 (and other isolation circuit examples in accordance with this description) may provide a galvanic isolation barrier between two different power domains. In at least one example, packaged IC 100 can include a direct current (DC)-to-DC converter having a transformer as integrated isolation circuit 108. In at least one example, the DC-to-DC converter comprises circuits in first semiconductor die 101 and second semiconductor die 102 coupled via transformer 108a of integrated isolation circuit 108. Accordingly, first semiconductor die 101 may include circuits, such as a first power circuit 101a (e.g., half-bridge circuit or a full-bridge circuit) and a driver circuit 101b, for providing a voltage and a current from other circuit to a primary winding of transformer 108a. In at least one example, the voltage and the current are provided from a power supply for a printed circuit board (PCB) on which package substrate 110 is mounted. The PCB may be used to power a device such as a motor or a computing device. In at least one example, second semiconductor die 102 may include a bridge circuit and a driver and regulation circuit for receiving a voltage and a current from a secondary winding of the transformer and providing one or more regulated output voltages and/or currents for use by a load on the PCB. The load may be an application-specific integrated circuit (ASIC), a field-programmable gate array (FPGA), a microcontroller, a processor, etc. In at least one example, first and second semiconductor dies 101 and/or 102 may represent controller circuit, current and voltage sensors, gate drivers for insulated-gate bipolar transistors, gate drivers for field effect transistors (FETs), etc.

In at least one example, transformer 108a is a figure-of-B shaped transformer comprising a primary winding and a secondary winding. In at least one example, the primary winding is on a top metal layer of package substrate 110 having an isolation barrier between the primary winding and surfaces of first and second semiconductor dies 101 and 102, respectively.

In at least one example, the isolation barrier is a first isolation barrier and includes part of package substrate 110 and part of a mold compound surrounding first and second semiconductor dies 101 and 102, respectively. The first isolation barrier provides isolation between first and second semiconductor dies 101 and 102 and transformer 108a that different power supply domains can be used for first and second semiconductor dies 101 and 102 while allowing first and second semiconductor dies 101 and 102 to overlap transformer 108a. In at least one example, a second isolation barrier is formed between the primary winding and the secondary winding of transformer 108a and includes package substrate 110. The second isolation barrier allows the metal layer for the primary winding to now have smaller gaps (e.g., reduced clearance specification).

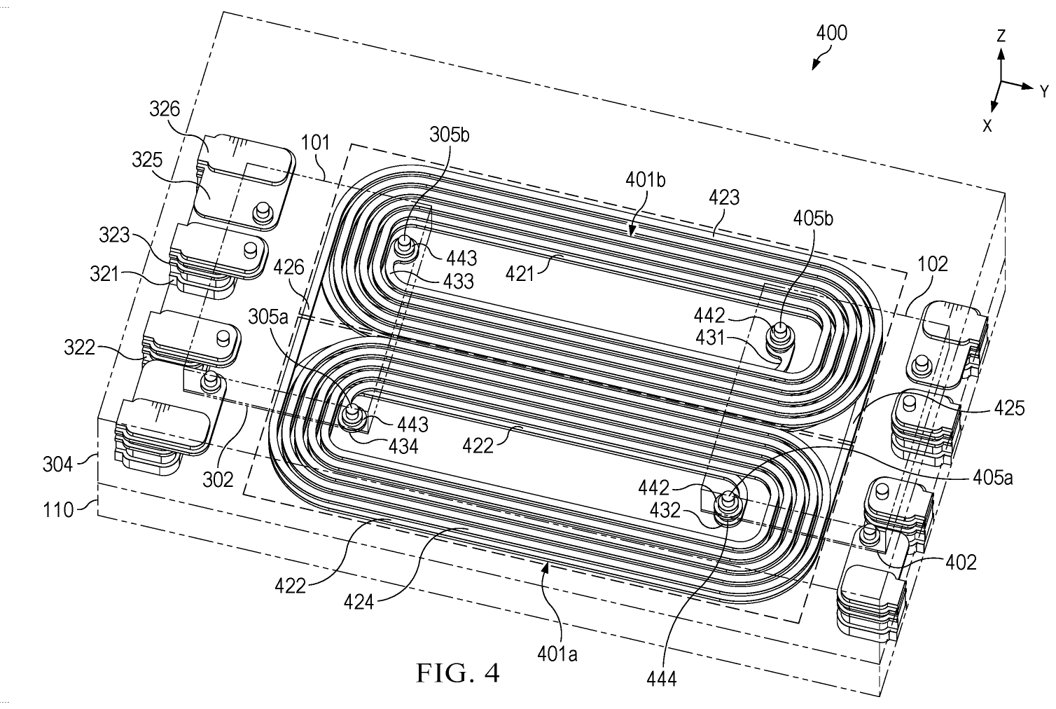

In at least one example, integrated isolation circuit 108 may include one or more isolation circuits. In at least one example, integrated isolation circuit 108 includes multiple transformers, for instance as shown in FIGS. 4, 5, 6, 7A, and 7B.

FIG. 1B is a schematic depicting a packaged IC 120 having an integrated isolation circuit comprising a power transformer and one or more data transformers, in accordance with at least one example. In at least one example, first semiconductor die 101 and second semiconductor die 102 include first and second signals circuits 101c and 102c, respectively, that are coupled via a data transformer 108b (or a set of data transformers), which is also part of the isolation circuit. In at least one example, first and second signals circuits 101c and 102c provide bidirectional signaling via interconnects 211 and 212, respectively. In at least one example, interconnects 211 and 212 form one or more data channels and include full duplex communication buses. In at least one example, data transformer 108b (or the set of data transformers) are positioned within openings of the windings of power transformer 108a and within a footprint of power transformer 108a. In at least one example, first and second semiconductor dies 101 and 102 are flip-chip dies that allow connection with power transformer 108a and data transformer 108b below them with reduced interconnection.

In at least one example, first and second signals circuits 101c and 102c are used for sending and receiving signals between the first and second power semiconductor dies 101 and 102 to realize a DC-DC converter. In at least one example, first and second signals circuits 101c and 102c can be used for other functions such as telemetry, data signaling, buffering of analog input signals for an analog-to-digital converter, buffering of digital input signals for a digital-to-analog converter, etc. In at least one example, data transformer 108b can be multiplexed between sending internal data (e.g., feedback data from a secondary side back to a primary side within packaged IC 120) and external data (e.g., external to packaged IC 120).

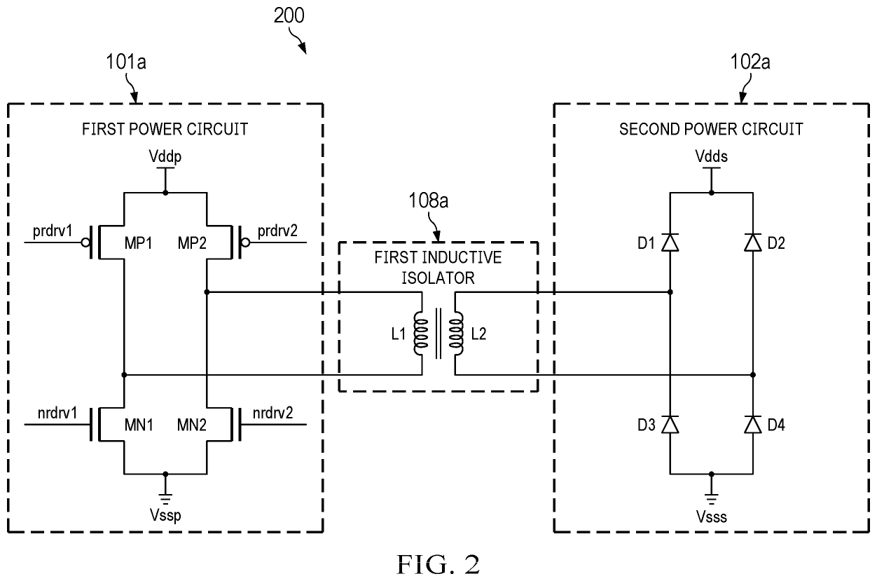

FIG. 2 is a schematic showing a DC-DC converter 200 formed on two semiconductor dies coupled by a power transformer, in accordance with at least one example. In at least one example, DC-DC converter comprises first power circuit 101a, second power circuit 102a, and power transformer 108a. In at least one example, first power circuit 101a comprises p-type transistors (e.g., field effect transistors (FETs)) MP1 and MP2 coupled to primary side power supply terminal Vddp, and n-type transistors MN1 and MN2 coupled to primary side ground terminal Vssp. Transistor MP1 is controllable by pdrv1, transistor MP2 is controllable by pdrv2,transistor MN1 is controllable by ndrv1, and transistor MN2 is controllable by ndrv2. Transistors MP1 and MP2 are high-side switches while transistors MN1 and MN2 are low-side switches. High-side switches are turned on and off by pdrv1 and pdrv2. In at least one example, data circuits 101b and/or 102b generate pdrv1 and pdrv2 signals based on a desired regulated output voltage and a reference voltage. Low-side switches are turned on and off by ndrv1 and ndrv2. In at least one example, data circuit 101b and/or 102b generate ndrv1 and ndrv2 signals based on the desired regulated output voltage and the reference voltage. High-side switches are coupled in series with low-side switches, and coupled to primary winding L1 (e.g., top winding) of transformer 108a.

In at least one example, second semiconductor die 102 includes two sets of diodes that are coupled in parallel. These diodes include diode D1 and D2 coupled to secondary side power supply terminal Vdds, and diode D3 and D4 coupled to secondary side ground terminal Vsss and to diodes D1 and D2. The two sets of diodes are coupled to the secondary winding L2 (bottom winding) of power transformer 108a. Power can be transmitted from the primary side power supply Vddp via the switching of first power circuit 101a and transformer 108a to second power circuit 102a and provided via the second side power supply terminal Vdds. Diodes D1, D2, D3, and D4 can provide rectification. As discussed herein, the secondary winding is in a metal layer below the metal layer of the primary winding and separated by a via metal layer. While DC-DC converter 200 is illustrated as one example, other examples of DC-DC converters can be employed that use power transformer 108a as an isolation circuit.

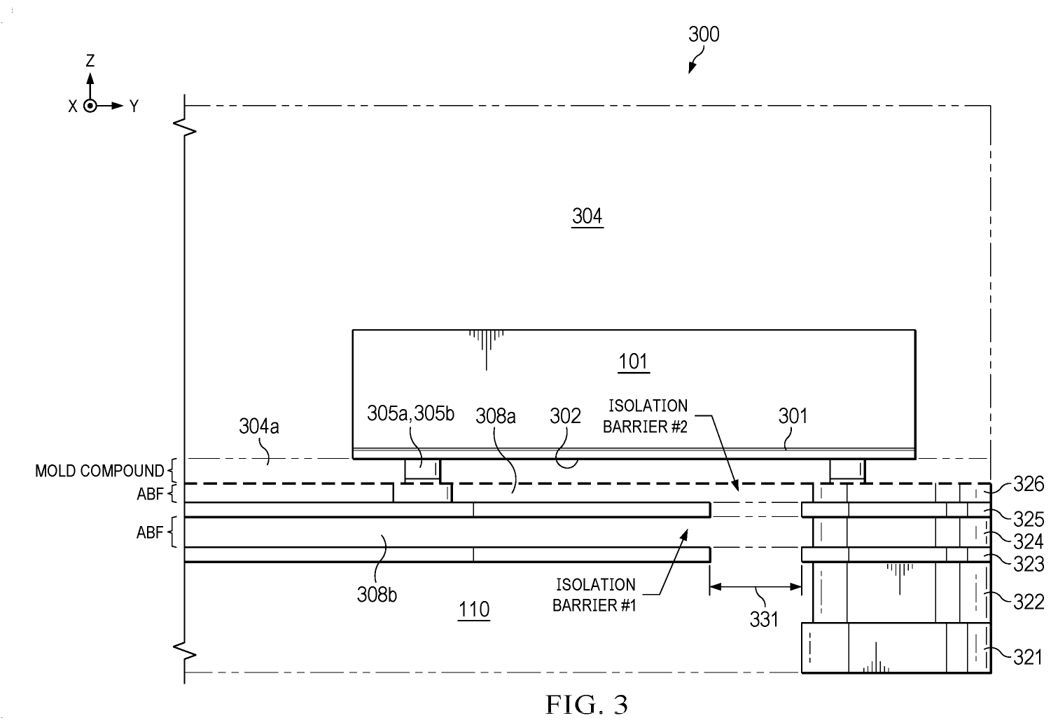

FIG. 3 is a schematic illustrating a cross section of a packaged IC 300 with at least two barrier layers adjacent to windings in an isolation barrier, in accordance with at least one example. In at least one example, packaged IC 300 includes package substrate 110, first semiconductor die 101, second semiconductor die 102 (not shown), and mold compound 304 surrounding first semiconductor die 101 and second semiconductor die 102. In at least one example, mold compound 304 may have any suitable form such as a bulk mold compound, a sheet mold compound, an insulation build-up film, etc. In at least one example, semiconductor die 101 has a metal layer 301 (e.g., part of a metallization structure) and a first surface 302 facing package substrate 110.

In at least one example, packaged IC 300, including package substrate 110 and first and second semiconductor dies 101 and 102, is or forms a flat no-leads package, in particular a dual-flat no-leads (DFN) package. In at least one example, contact pads area used to mount packaged IC 300 to an external package substrate are arranged such that packaged IC 300 forms a quad-flat no-leads (QFN) package. In at least one example, package substrate 110 is composed of Ajinomoto build-up film (ABF). In at least one example, package substrate 110 comprises a laminate material.

In at least one example, the material for package substrate 110 has a thickness in the z-direction sufficient to provide a galvanic isolation barrier that can withstand at least 5 kilovolts (kV) root mean square (RMS) for 60 seconds in one example and at least 2.5 kV RMS for 60 seconds in another example. However, different isolation ratings may be achievable based at least in part on the type and thickness of the material for package substrate 110.

In at least one example, using mold compound 304, such as a compression molding film, as the material for package substrate 110, instead of a laminate, allows for a smaller critical separation between the first and second windings of transformer 108a while maintaining the same voltage insulation and allows for improved thermal performance of integrated isolation circuit 108. Also, making package substrate 110 using routable lead frame technology allows for thicker copper traces (e.g., 30-35 micrometers or thicker, for instance 1%, 5%, or 10% thicker) and smaller metal width and spacing (e.g., 30×30 micrometers² or less, for instance 1%, 5%, or 10% less). This may lead to an improved efficiency of power transformer 108a by allowing an increased quality factor. Integrating power and data transformers 108a and 108b into package substrate 110 allows for smaller packaged IC sizes (e.g., 5.0×3.0×0.8 millimeters³ or less, for instance 1%, 5%, or 10% less).

As used herein, critical separation may refer to one or more minimum distances between first and second circuit elements (e.g., the primary and secondary windings) of an isolation circuit that to achieve a particular isolation rating without a voltage breakdown of the isolation material between the first and second circuit elements. Accordingly, by using different types of isolation materials for package substrate 110, e.g., different types of mold compounds individually or in combination, the critical separation between primary and secondary windings can be adjusted, for instance to meet desired creepage and clearance for packaged IC 300 and to achieve lower creepage and clearance than achievable using laminate as isolation material.

In at least one example, package substrate 110 is a multi-layer structure made using routable lead frame (RLF) technology. In at least one example, package substrate 110 is made using a flipped routable lead frame. A metal layer, as used herein, is a layer of metal within which is formed metallic elements of a package substrate such as contact pads, vias, electrical traces, a thermal/ground pad, and circuit elements of an isolation circuit. Metal layers are positioned in substantially parallel planes to one another and are substantially planar within allowable tolerances as defined by the technology used to make the package substrate. Any suitable metal may be used to form the metal layers, such as copper, aluminum, and gold.

In at least one example, package substrate 110 comprises a first metal layer 321 which can include pin interfaces to connect to pins or pads of packaged IC 300. In at least one example, package substrate 110 comprises a first via layer 322 over first metal layer 321, a second metal layer 323 over first via layer 322, a second via layer 324 over second metal layer 323, a third metal layer 325 over second via layer 324, and a third via layer 326 over third metal layer 325. In at least one example, first metal layer 321 is thicker (in the z-direction) than second metal layer 323 and third metal layer 325. In at least one example, first via layer 324 is thicker (in the z-direction) than second via layer 324 and third via layer 326. While package substrate 110 is illustrated with three metal layers, in at least one example package substrate 110 can have two metal layers (e.g., for first and second windings) and first via layer 322 connects to pins.

In at least one example, package substrate 110 is fabricated by forming third via layer 326 followed by third metal layer 325, second via layer 324, second metal layer 323, first via layer 322, and first metal layer 321. Thereafter, package substrate 110 is flipped and electrically coupled to first and second semiconductor dies 101 and 102, respectively. By flipping package substrate 110, first surface 302 and third via layer 326 are closer to a mounting surface of first and second semiconductor dies 101 and 102. Upon flipping of package substrate 110 after fabrication, third metal layer 325 is now below third via layer 326. In other examples, package substrate 110 may be formed as shown without flipping.

In at least one example, the thickness (in the z-direction) of first metal layer 321 is larger than the thicknesses (in the z-direction) of second metal layer 323 and third metal layer 325. In at least one example, the thickness (in the z-direction) of first via layer 322 is larger than the thickness (in the z-direction) of second via layer 324. In at least one example, the thickness (in the z-direction) of second via layer 324 is larger than the thickness (in the z-direction) of third via layer 326. In at least one example, the thickness (in the z-direction) of third via layer 326 and spacing between first surface 302 of first semiconductor die 101 from a top surface of third via layer 326 form the region for isolation barrier. This region of isolation barrier includes insulation material 308a (e.g., ABF material) and insulation material 304a (e.g., part of mold compound 304).

In at least one example, first and second semiconductor dies 101 and 102 are mounted on first surface 302 (e.g., top surface) of package substrate 110. Package substrate 110 further includes pins or pads on a second surface of package substrate 110 opposing the first surface, where the pins or pads are in first metal layer 321. In at least one example, first semiconductor die 101 is coupled to at least some of the pins in first metal layer 321, and second semiconductor die 102 is coupled to at least some of the pins in first metal layer 321 via first via layer 322 and/or a combination of vias and metal layers discussed herein in package substrate 110. The pins in first metal layer 321 allow first semiconductor die 101 and second semiconductor die 102 to communicate with one or more devices outside of package substrate 110.

In at least one example, the primary winding of transformer 108a is formed in third metal layer 325 while the secondary winding of transformer 108a is formed in second metal layer 324. In at least one example, transformer 108b is also formed in third metal layer 325 and second metal layer 324. In at least one example, first metal layer 321 may be used for routing signals from first semiconductor die 101 and second semiconductor die 102 out to a printed circuit board (PCB) via pin interfaces.

In at least one example, a region exists between surfaces (e.g., first surface 302) of first semiconductor die 101 and second semiconductor die 102 and the primary winding (e.g., top winding) on third metal layer 325 of power transformer 108a. In at least one example, the region forms a first isolation barrier which comprises part (herein insulation material 304a) of mold compound 304 and part (herein insulation material 308a) of package substrate 110. The vertical distance created between first surface 302 and primary winding in third metal layer 325 from the first isolation barrier allows both first and second semiconductor dies 101 and 102 to overlap transformer 108a even when the power domains of first and second semiconductor dies 101 and 102 are substantially different. In at least one example, a second isolation barrier 308b exists between the primary winding on third metal layer 325 and the secondary winding on second metal layer 323 of the two windings of power transformer 108a.

In at least one example, the first isolation barrier provides enough isolation between first and second semiconductor dies 101 and 102 and transformer 108a that different power supply domains can be used for first and second semiconductor dies 101 and 102, respectively, while allowing first and second semiconductor dies 101 and 102, respectively, to overlap transformer 108a. By overlapping transformer 108a, overall size of packaged IC 300 reduces. In at least one example, third metal layer 325 for the primary winding can now have smaller gaps (e.g., reduced clearance specification) between other metal segments on the same metal layer because of the first isolation barrier formed by insulation material 304a of mold compound 304 and insulation material 308a (e.g., ABF) of package substrate 110.

In at least one example, first semiconductor die 101 is coupled to the primary winding of transformer 108a through metal posts or pillars 305a and/or 305b. In at least one example, metal posts or pillars 305a and/or 305b are coupled to metal layer 301 of first semiconductor die 101. In at least one example, transformer 108b has a first portion in a first opening of the first winding of transformer 108a and has a second portion in a second opening of the first winding of transformer 108a. In at least one example, the first portion and the second portion of transformer 108b are coupled through metal layer 301 and through metal posts or pillars 305a and 305b. In at least one example, the secondary winding of transformer 108a is coupled to second semiconductor die 102 through second via layer 324.

In at least one example, first metal layer 321 forms the pins and at the same time couples through first via layer 322, second metal layer 323, second via layer 324, and third metal layer 325 to third via layer 326. Third via layer 326 electrically couples to first semiconductor die. In at least one example, first metal layer 321 together with first via layer 322 provides more vertical clearance (in the z-direction) between second metal layer 323 and air underneath package substrate 110 to reduce fringing electric field below package substrate 110 on the opposite side (e.g., reduces fringe electric field between second metal layer 323 and second semiconductor die 102 not shown in FIG. 3). This fringe electric field if not reduced may ionize the air and compromise galvanic isolation by the first and second isolation barriers. As discussed herein, increasing the vertical separation between the primary winding (e.g., top winding) on third metal layer 325 of power transformer 108a and air below package substrate 110 reduces the fringe electric field, in accordance with at least one example.

In at least one example, a lateral separation 331 (here in the y-direction) is provided between the primary winding of third metal layer 325 and routing traces on third metal layer 325 along a periphery of package substrate 110. In at least one example, lateral separation 331 is provided because the primary winding may be in a different voltage domain (e.g., voltage domain of second semiconductor die 102) than a voltage domain of routing traces on third metal layer 325 which may be the voltage domain of first semiconductor die 101.

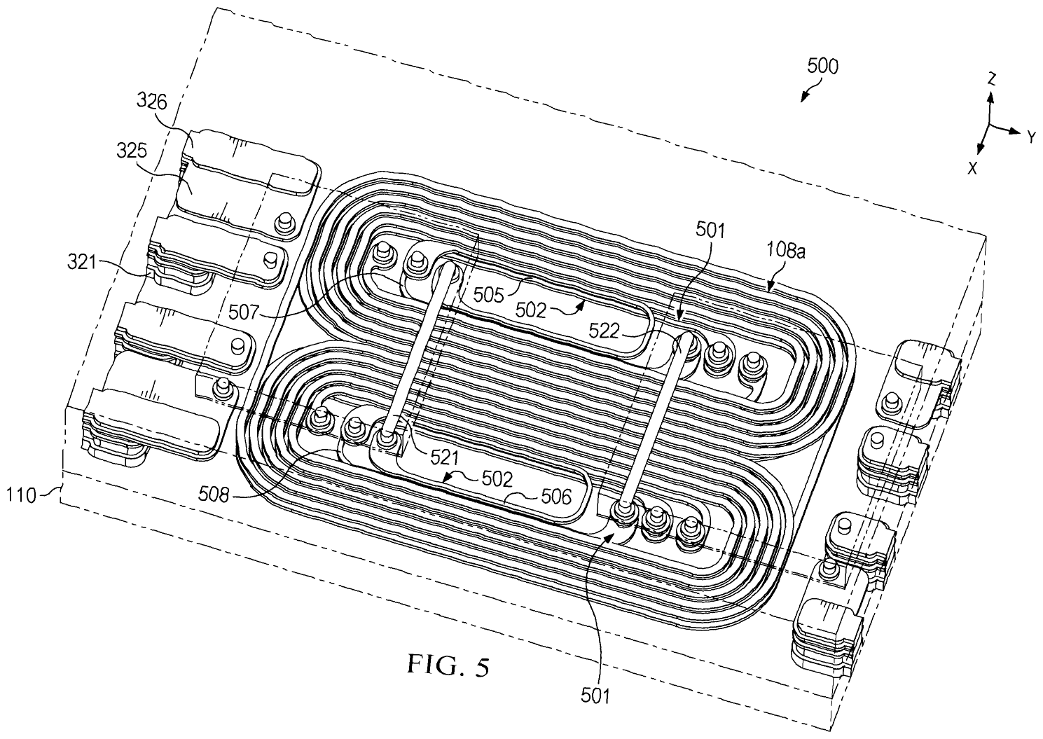

FIG. 4 is a schematic illustrating an isometric view of packaged IC 400 having a power transformer, in accordance with at least one example. FIG. 5 is a schematic illustrating an isometric view of packaged IC 500 having the power transformer and a data transformer, in accordance with at least one example.

In at least one example, packaged IC 400 comprises package substrate 110 having first metal layer 321, second metal layer 323 on first metal layer 321, and first via layer 322 (which includes first via(s)) coupled between first metal layer 321 and second metal layer 323. Package substrate 110 further includes second via layer 324 (which includes second via(s)) coupled between second metal layer 323 and third metal layer 325 and third vias of third via layer 325 on third metal layer 325. In at least one example, first metal layer 321 includes pins for coupling to other devices (not shown). In at least one example, third metal layer 325 includes primary winding 401a (herein also referred to as second winding) while second metal layer 323 includes secondary winding 401b (herein also referred to as first winding) of power transformer 108a. In at least one example, primary winding 401a and secondary winding 401b are in a figure-of-B configuration.

In at least one example, package substrate 110 includes an insulation material (e.g., ABF) covering first metal layer 321, second metal layer 323, third metal layer 325, first vias (e.g., vias of first via layer 322), second vias (e.g., vias on second via layer 324), and third vias (e.g., vias of third via layer 326), and exposing surfaces of the pins and third via layer 326. In at least one example, first metal posts or pillars 305a and 305b are coupled between first semiconductor die 101 and the exposed surface of a first subset of the third vias (e.g., vias including via 443 of third via layer 326). In at least one example, second metal posts or pillars 405a and 405b coupled between second semiconductor die 102 and the exposed surfaces of a second subset of the third vias (e.g., vias including via 442 of third via layer 326). In at least one example, mold compound 304 covers first and second semiconductor dies 101 and 102, respectively, and first metal posts or pillars 305a and 305b, and second metal posts or pillars 405a and 405b.

In at least one example, first semiconductor die 101 has a first surface opposing primary winding 401a while second semiconductor die 102 has a second surface opposing primary winding. In at least one example, the first surface and primary winding 401a are separated by insulation material 308a and insulation material 304a (e.g., part of mold compound 304). In at least one example, the second surface and primary winding 401a are also separated by insulation material 308a and insulation material 304a (e.g., part of mold compound 304). In at least one example, first semiconductor die 101 is coupled to primary winding 401a via first subset of the third vias (e.g., vias including via 443 of third via layer 326) while and second semiconductor die 102 is coupled to secondary winding 401b via second subset of third vias (e.g., vias including via 442 of third via layer 326) and a subset of second vias 443. In at least one example, first semiconductor die 101 and primary winding 401a are part of a first voltage domain while second semiconductor die 102 and secondary winding 401b are part of a second voltage domain different from the first voltage domain.

In at least one example, secondary winding 401b includes a first coil portion 421, a second coil portion 422, and a first straight portion 425 coupled between first coil portion 421 and second coil portion 422. In at least one example, first straight portion 425 is below second semiconductor die 102. In at least one example, primary winding 401a includes a third coil portion 423, a fourth coil portion 424, and a second straight portion 426 coupled between third coil portion 423 and fourth coil portion 424. In at least one example, second straight portion 426 is below first semiconductor die 101.

In at least one example, first coil portion 421 has a first end 431 coupled to a first one of the second vias (e.g., vias including via 444 of second via layer 324) and a first one of the third vias (e.g., vias including via 442 of third via layer 326). In at least one example, second coil portion 422 has a second end 432 coupled to a second one of the second vias (e.g., vias include via 444 on second via layer 324) and a second one of the third vias (e.g., vias including via 442 on third via layer 326). In at least one example, third coil portion 423 has a third end 433 coupled to a third one of the third vias (e.g., vias including via 443 of third via layer 326), and the fourth coil portion 424 has a fourth end 434 coupled to a fourth one of the third vias (e.g., vias including via 433 of third via layer 326). In at least one example, first coil portion 421 overlaps with third coil portion 423, and second coil portion 422 overlaps with fourth coil portion 424. In at least one example, first coil portion 421, the second coil portion 422, and the first straight portion 425 form a first figure-of-B topology, and the third coil portion 423, the fourth coil portion 424, and the second straight portion 426 form a second figure-of-B topology.

Referring to FIG. 5, packaged IC 500 includes a second transformer formed in the openings of first winding 401a and second winding 401b. In at least one example, the second transformer is data transformer 108b. In at least one example, second metal layer 323 includes a first winding 501 of data transformer 108b, and third metal layer 325 includes a second winding 502 of data transformer 108b. In at least one example, first winding 501 of second transformer 108b includes a seventh coil portion 507 and an eighth coil portion 508. In at least one example, second winding 502 of data transformer 108b includes a fifth coil portion 505 and a sixth coil portion 506, where first winding 501 is below second winding 502, and where second winding 502 is closer to first surface 302 than first winding 501. In at least one example, fifth coil portion 505 and seventh coil portion 507 are within a footprint of first coil portion 421 and third coil portion 423. In at least one example, sixth coil portion 506 and eighth coil portion 508 are within a footprint of the second coil portion 422 and fourth coil portion 424.

In at least one example, fifth coil portion 505 and sixth coil portion 506 are coupled together by a first straight portion 521, which can be part of metal layer 301 of first semiconductor die 101. An end of fifth coil portion 505 is coupled to one end of first straight portion 521 through one of the third via(s) (e.g., vias of third via layer 326), and an end of sixth portion 506 is coupled to another end of first straight portion 521 through one of another of the third via(s) (e.g., vias of third via layer 326). In at least one example, first straight portion 521 is taped at or near the center or middle of first straight portion 521 as a center terminal for a data transmitter or receiver. The data transmitter or receiver can be part of first signal circuit 101c, in accordance with at least one example.

In at least one example, seventh coil portion 507 and eighth coil portion 508 are coupled together by a second straight portion 522, which can also be part of metal layer 301 of second semiconductor die 102. An end of eighth coil portion 508 is coupled to second straight portion 522 through the second via (e.g., via of second via layer 324) alone or in combination with the third via (e.g., via of third via layer 326). In at least one example, an end of seventh coil portion 507 is coupled to second straight portion 522 through the second via (e.g., via of second via layer 324) alone or in combination with the third via (e.g., via of third via layer 326). In at least one example, second straight portion 522 is taped at or near the center or middle of second straight portion 522 as a center terminal for a data transmitter or receiver. The data transmitter or receiver can be part of second signal circuit 102c, in accordance with at least one example. In at least one example, fifth coil portion 505 and seventh coil portion 507 are within an opening of a footprint of first and third coil portions 421 and 423, respectively.

In at least one example, fifth coil portion 505 and seventh coil portion 507 are within an opening of a footprint of the first and third coil portions 421 and 423, respectively. In at least one example, sixth coil portion 506 and eighth coil portion 508 are within an opening of a footprint of footprint of second coil portion 422 and fourth coil portion 424.

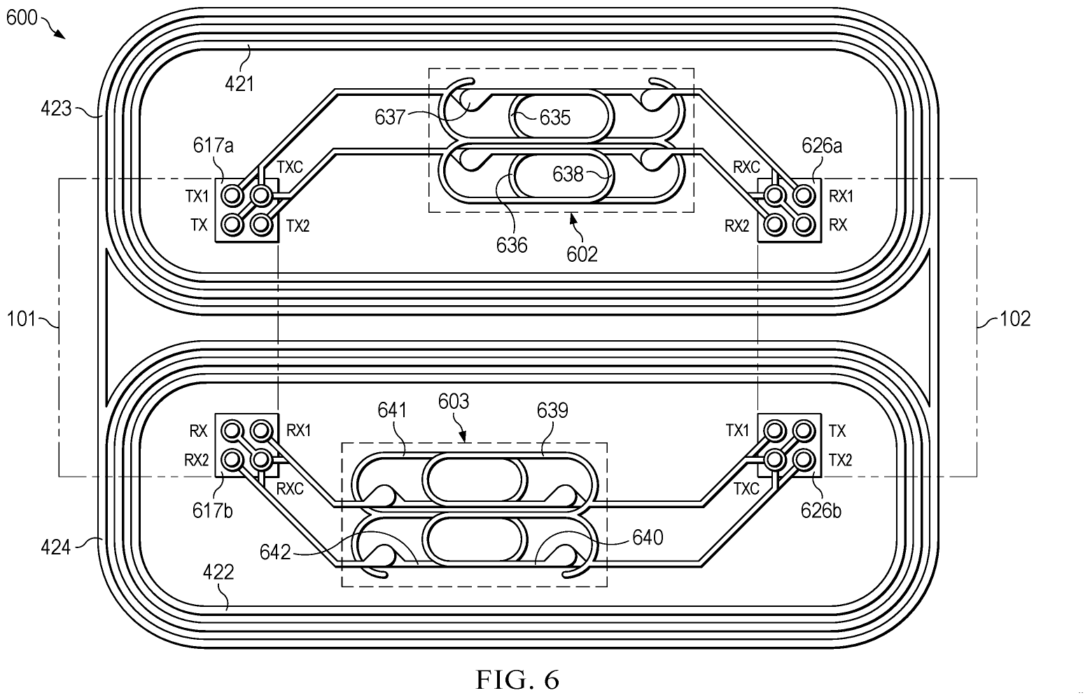

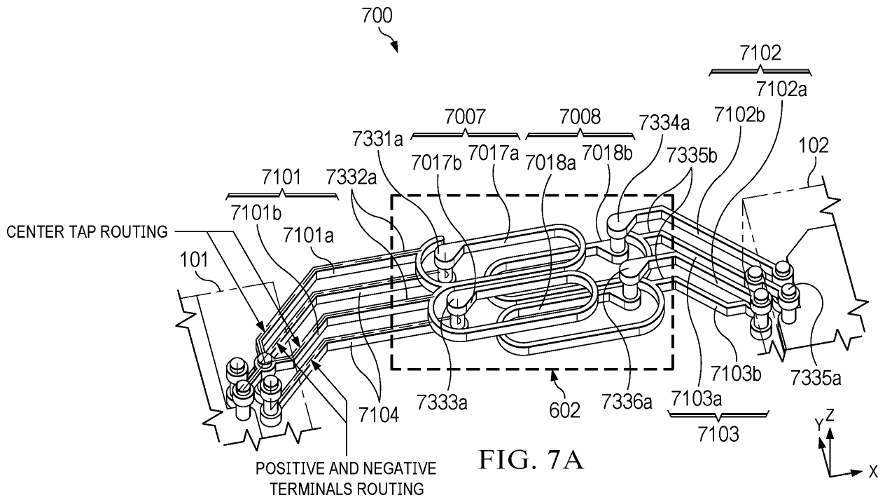

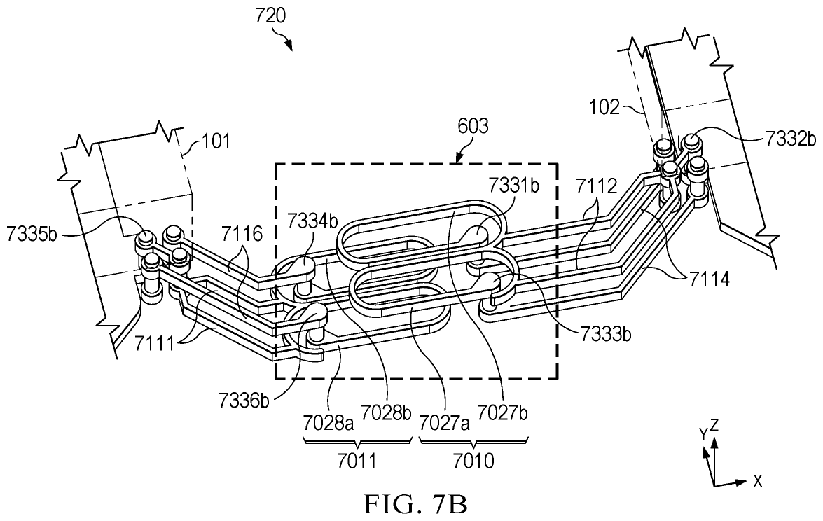

FIG. 6 is a schematic illustrating a top view of packaged IC 600 having power transformer 108a and two data transformers, in accordance with at least one example. FIGS. 7A-B are schematics illustrating isometric views of packaged ICs 700 and 720 having the data transformers, in accordance with some examples. In at least one example, packaged IC 600 includes a second transformer 602 (e.g., one of data transformers 108b) within the opening of the footprint of first coil portion 421 and third coil portion 423 of power transformer 108a. In at least one example, packaged IC 600 includes a third transformer 603 (e.g., one of data transformers 108b) within the opening of the footprint of second coil portion 422 and fourth coil portion 424 of power transformer 108a.

In at least one example, second transformer 602 has a first winding comprising fifth coil portion 635 and sixth coil portion 636 in second metal layer 323. In at least one example, ends of fifth coil portion 635 and sixth coil portion 636 are coupled to a receiver circuit 626a of second signal circuit 102c. In at least one example, second transformer 602 has a second winding comprising seventh coil portion 637 and eighth coil portion 638 in third metal layer 325. In at least one example, ends of seventh coil portion 637 and eighth coil portion 638 are coupled to a transmitter circuit 617a of second signal circuit 101c.

In at least one example, third transformer 603 has a first winding comprising eleventh coil portion 641 and twelfth coil portion 642 in second metal layer 323. In at least one example, ends of eleventh coil portion 641 and twelfth coil portion 642 are coupled to a transmitter circuit 617b of second signal circuit 102c. In at least one example, third transformer 603 has a second winding comprising ninth coil portion 639 and tenth coil portion 640 in third metal layer 325. In at least one example, ends of ninth coil portion 639 and tenth coil portion 640 are coupled to a receiver circuit 626b of second signal circuit 101c. In at least one example, transmitter circuit 617a is a first differential transmitter while transmitter circuit 617b is a second differential transmitter. In at least one example, receiver circuit 626a is a first differential receiver while receiver circuit 626b is a second differential receiver.

In at least one example, second transformer 602 includes a second primary winding 7007 and a second secondary winding 7008, which partially overlaps with each other. In at least one example, third transformer 603 includes a third primary winding 7010 and a third secondary winding 7011, which also partially overlap with each other. In at least one example, second and third transformers 602 and 603, respectively, are within the openings of the footprint of power transformer 108a. In at least one example, winding pattern and connection of taps of second and third transformers 602 and 603, respectively, can improve symmetry in the connection taps. By achieving more symmetry in routing of connection taps, common mode rejection improves.

In at least one example, second primary winding 7007 is in third metal layer 325 and second secondary winding 7008 is on second metal layer 323 below first metal layer 325. In at least one example, each of second primary winding 7007 and second secondary winding 7008 has two windings in a figure-of-8 configuration. The windings can have oval shapes, or other winding shapes such as circular shapes, rectangular shapes, square shapes, etc.

In at least one example, second primary winding 7007 has a first primary side terminal 7331a, a center tap 7332a, and a second primary side terminal 7333a. In at least one example, first primary side terminal 7331a and second primary side terminal 7333a couple to outputs of a transmitter circuit 617a (e.g., differential transmitter circuit) while center tap 7332a is coupled to a ground. In at least one example, the center taps of second and third transformers 602 and 603 can be positioned away from the footprints of second and third transformers 602 and 603. In at least one example, center tap 7332a is positioned outside the footprint of second transformer 602 and is coupled to second primary winding 7007 by a center tap metal interconnect 7101 that extends laterally between second transformer 602 and center tap 7332a. In at least one example, the center tap metal interconnect can have matched/balanced branch portions 7101a and 7101b.

In at least one example, two coil portions 7017a and 7017b extend from the branch/straight portions forming second primary winding 7007, where coil portion 7017a terminates at first primary side terminal 7331a and coil portion 7017b terminates at second primary side terminal 7333a. First primary side terminal 7331a and second primary side terminal 7333a are coupled to transmitter circuit (TX) 617a via a pair of metal interconnects 7104, which are formed in second metal layer 323 and under center tap metal interconnect 7101. Symmetry/matching can be achieved by, for example, having pair of metal interconnects 7104 overlapping with branch portions 7101a and 7101b of center tap metal interconnect 7101. In both cases, the pair of metal interconnects 7104 can have matched capacitive loading due to matched overlap with the center tap metal interconnect 7101, which can improve symmetry and matching between the differential signals on metal interconnects 7104.

In at least one example, center tap 7332a is formed under first semiconductor die 101 and coupled to first signal circuit 101c through a metal pillar or post (e.g., copper pillar) while first primary terminal 7331a and second primary side terminal 7333a are away first semiconductor die 101 because second primary winding 7007 is not overlapping first signal circuit 101c.

In at least one example, second secondary winding 7008 has similar or exact topology as second primary winding 7007 with a portion (e.g., half) of it overlapping second secondary winding 7008. In at least one example, center tap 7335a is positioned outside the footprint of second transformer 602 and is coupled to second secondary winding 7008 by a center tap metal interconnect 7102 that extends laterally between second transformer 602 and center tap 7335a. In at least one example, the center tap metal interconnect can have balanced/matched branch portions 7102a and 7102b. Two coil portions 7018a and 7018b extend from the branch portions forming second secondary winding 7008, where coil portion 7018a terminates at first secondary side terminal 7334a and coil portion 7018b terminates at second primary side terminal 7336a. First secondary side terminal 7334a and second secondary side terminal 7336a are coupled to receiver circuit (RX) 626a of second signal circuit 102c via a pair of metal interconnects 7103, which are formed in second metal layer 323 and under the center tap metal interconnect 7102. In at least one example, center tap 7335a is coupled to another ground node. Symmetry/matching can be achieved by, for example, having pair of metal interconnects 7103 (e.g., branch portions 7103a and 7103b) overlapping with balanced/matched branch portions 7102a and 7102b of center tap metal interconnect 7102.

In at least one example, third transformer 603 has similar or exact topology as second transformer 602. For example, center tap 7332b is positioned outside the footprint of third transformer 603 and is coupled to third primary winding 7010 by a center tap metal interconnect 7112 that extends laterally between third transformer 603 and center tap 7332b. In at least one example, third primary winding 7010 includes coil portions 7027a and 7027b that terminate at, respectively, first primary side terminals 7331b and second primary side terminals 7333b. In at least one example, a pair of metal interconnects 7114 couples between second signal circuit 102c and first primary side terminals 7331b and second primary side terminals 7333b. In at least one example, symmetry/matching can be achieved by having pair of metal interconnects 7114 overlapping with the branch portions of metal interconnect 7112 or being equal distance from the straight portion of metal interconnect 7112. In at least one example, branch portions of metal interconnect 7112 are coupled to receiver circuit (RX) 626b of second signal circuit 102c.

In at least one example, center tap 7335b is also positioned outside the footprint of third transformer 603 and is coupled to third secondary winding 7011 by a center tap metal interconnect 7111. In at least one example, third secondary winding 7010 includes coil portions 7028a and 7028b that terminate at, respectively, first secondary side terminal 7334b and second secondary side terminal 7336b. In at least one example, a pair of metal interconnects 7116 couples between receiver (RX) 617b of first signal circuit 101c and first secondary side terminals 7334b and second secondary side terminals 7336b. In at least one example, symmetry/matching can be achieved by having pair of metal interconnects 7116 overlapping with the branch portions of metal interconnect 7111 or being equal distance from the straight portion of metal interconnect 7111.

In at least one example, second primary winding 7007 and second secondary winding 7008 are electrically and galvanically isolated using an isolation material of package substrate 110, which forms a galvanic isolation barrier between two different power/data domains of first signal circuit 101c and second signal circuit 102c. In at least one example, first signal circuit 101c is powered using a voltage supply and ground connection associated with a first power domain. In at least one example, second signal circuit 102c is powered using a different voltage supply and ground connection associated with a second power domain.

In at least one example, using a mold compound as the isolation material of package substrate 110, instead of a laminate, allows for a smaller critical separation between second primary winding 7007 and second secondary winding 7008 while maintaining the same voltage insulation and allows for improved thermal performance of integrated isolation circuit 108.

Both second and third transformers 602 and 603, respectively, can be formed in two metal layers. In at least one example, second primary winding 7007, center tap metal interconnects 7101, metal interconnects 7103, third primary winding 7010, center tap metal interconnects 7112, and metal interconnects 7111 can be formed on a top metal layer (e.g., third metal layer 325). Second secondary winding 7008, center tap metal interconnects 7102, metal interconnects 7114, third secondary winding 7011, and center tap metal interconnects 7111 can be formed on second metal layer 323 below first metal layer 325. The two-layer configuration is achieved by trading off coupling between primary and secondary windings to achieve a layout symmetry of the primary and secondary windings that result in lower parasitic barrier capacitance and less electromagnetic radiation.

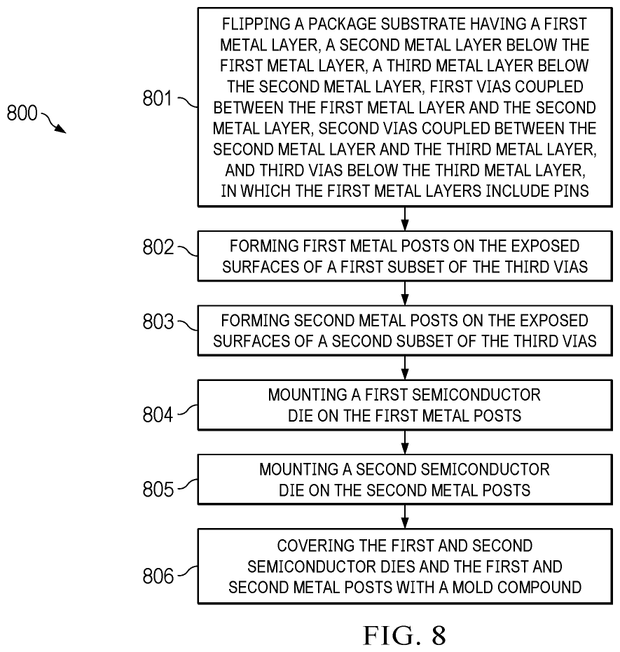

FIG. 8 is a flowchart 800 of a method of forming the packaged IC, in accordance with at least one example. Various blocks of flowchart 800 are shown in a particular order. The order can be modified. For example, some blocks can be performed before others and some blocks may be performed in parallel. Flowchart 800 may be implemented using routable lead frame technology and may be performed as part of a process for manufacturing packaged ICs, such as packaged ICs of FIGS. 3, 4, 5, 6, 7A, and 7B.

At block 801, package substrate 110 is flipped after forming or fabricating layers in it. Package substrate 110 is formed by fabricating third via layer 326 followed by third metal layer 325, second via layer 324, second metal layer 323, first via layer 322, and first metal layer 321. Electroplating, etching, and patterning of metal is used to form the layers and filling or pressing dielectric material (e.g., ABF) is performed regularly after each layer is fabricated. After the layers are fabricated and dielectric material is surrounded around the fabricated layers, the resulting substrate, package substrate 110, is flipped vertically along the z-axis which results in third via layer 326 being the top layer facing first surface 302. In at least one example, first metal layer 321 is connected to contact pads or pins.

At block 802, first metal posts or pillars 305a, 305b are formed on exposed surfaces of a first subset of the third vias (e.g., vias of third via layer 326). At block 803, second metal posts or pillars 405a, 405b are formed on exposed surfaces of a second subset of the third vias (e.g., vias of third via layer 326). At block 804, first semiconductor die 101 is mounted on first metal posts or pillars 305a, 305b. At block 805, second semiconductor die 102 is mounted on second metal posts or pillars 405a, 405b. In at least one example, at block 806, first and second semiconductor dies 101 and 102, respectively, and first metal posts or pillars 305a, 305b and second metal posts or pillars 405a, 405b are covered with a mold compound.

In at least one example, the method of forming the packaged IC comprises covering first metal layer 321, second metal layer 323, and third metal layer 325 with insulation material (e.g., ABF). In at least one example, the method of forming the packaged IC comprises covering first via layer 322, second via layer 323, and third via layer 326 with the insulation material. In at least one example, the method of forming the packaged IC comprises exposing surfaces of the pins on first metal layer 321 and the third vias (e.g., vias of third via layer 326). As discussed herein, second metal layer 323 includes first winding 401a of power transformer 108a, while third metal layer 325 includes second winding 401b of power transformer 108a. In at least one example, first surface 302 of first semiconductor die 101 faces second winding 401b. Likewise, second surface 402 of second semiconductor die 102 faces second winding 401b. In at least one example, the method of forming the packaged IC comprises separating first surface 302 and second winding 401b by the insulation material and mold compound 304. In at least one example, the method of forming the packaged IC comprises separating second surface 402 and second winding 401b by the insulation material (e.g., ABF) and mold compound 304.

In at least one example, the method of forming the packaged IC comprises coupling first semiconductor die 101 to second winding 401b via the first subset of the third vias (e.g., vias including via 443 of third via layer 326). In at least one example, the method of forming the packaged IC comprises coupling second semiconductor die 102 to first winding 401a via second subset of the third vias (e.g., vias including via 442 of third via layer 326) and subset of the second vias (e.g., vias including via 444 of second via layer 324). As discussed herein, first semiconductor die 101 and second winding 401b are part of a first voltage domain, and second semiconductor die 102 and first winding 401a are part of a second voltage domain, wherein the second voltage domain is different from the first voltage domain.

The following are additional examples provided in view of the above-described implementations. Here, one or more features of example, in isolation or in combination, can be combined with one or more features of one or more other examples to form further examples also falling within the scope of the disclosure. As such, one implementation can be combined with one or more other implementation without changing the scope of disclosure.

Example 1 is a packaged integrated circuit comprising: a package substrate including: a first metal layer, a second metal layer on the first metal layer, a third metal layer on the second metal layer, first vias coupled between the first metal layer and the second metal layer, second vias coupled between the second metal layer and the third metal layer, and third vias on the third metal layer, in which the first metal layer include pins, the second metal layer includes a first winding of a transformer, and the third metal layer includes a second winding of the transformer; and an insulation material covering the first, second, and third metal layers and the first, second, and third vias, and exposing surfaces of the pins and the third vias; a first semiconductor die on the package substrate; a second semiconductor die on the package substrate; first metal posts coupled between the first semiconductor die and the exposed surfaces of a first subset of the third vias; second metal posts coupled between the second semiconductor die and the exposed surfaces of a second subset of the third vias; and a mold compound covering the first and second semiconductor dies and the first and second metal posts.

Example 2 is a packaged integrated circuit according to any example herein, in particular example 1, wherein the first semiconductor die has a first surface opposing the second winding, the second semiconductor die has a second surface opposing the second winding, the first surface and the second winding is separated by the insulation material and the mold compound, and the second surface and the second winding is separated by the insulation material and the mold compound.

Example 3 is a packaged integrated circuit according to any example herein, in particular example 2, wherein the first semiconductor die is coupled to the second winding via the first subset of the third vias, and the second semiconductor die is coupled to the first winding via the second subset of the third vias and a subset of the second vias; wherein the first semiconductor die and the second winding are part of a first voltage domain; and wherein the second semiconductor die and the first winding are part of a second voltage domain.

Example 4 is a packaged integrated circuit according to any example herein, in particular example 1, wherein the first winding includes a first coil portion, a second coil portion, and a first straight portion coupled between the first and second coil portions, the first straight portion being below the second semiconductor die; and wherein the second winding includes a third coil portion, a fourth coil portion, and a second straight portion coupled between the third and fourth coil portions, the second straight portion being below the first semiconductor die.

Example 5 is a packaged integrated circuit according to any example herein, in particular example 4, wherein the first coil portion has a first end coupled to a first one of the second vias and a first one of the third vias, and the second coil portion has a second end coupled to a second one of the second vias and a second one of the third vias; and wherein the third coil portion has a third end coupled to a third one of the third vias, and the fourth coil portion has a fourth end coupled to a fourth one of the third vias.

Example 6 is a packaged integrated circuit according to any example herein, in particular example 4, wherein the first coil portion overlaps with the third coil portion, and the second coil portion overlaps with the fourth coil portion.

Example 7 is a packaged integrated circuit according to any example herein, in particular example 4, wherein the first coil portion, the second coil portion, and the first straight portion form a first figure-of-B topology, and the third coil portion, the fourth coil portion, and the second straight portion form a second figure-of-B topology.

Example 8 is a packaged integrated circuit according to any example herein, in particular example 4, wherein the transformer is a first transformer, the second metal layer includes a first winding of a second transformer, and the third metal layer includes a second winding of the second transformer; wherein the second winding of the second transformer includes a fifth coil portion and a sixth coil portion; and wherein the first winding of the second transformer includes a seventh coil portion and an eighth coil portion.

Example 9 is a packaged integrated circuit according to any example herein, in particular example 8, wherein the fifth and seventh coil portions are within a footprint of the first and third coil portions; and wherein the sixth and eighth coil portions are within a footprint of the second and fourth coil portions.

Example 10 is a packaged integrated circuit according to any example herein, in particular example 8, wherein the fifth, sixth, seventh, and eighth coil portions are within a footprint of the first and third coil portions.

Example 11 is a packaged integrated circuit according to any example herein, in particular example 10, wherein the second metal layer includes a first winding of a third transformer, and the third metal layer includes a second winding of the third transformer, and wherein the third transformer is within the footprint of the second and fourth coil portions.

Example 12 is a packaged integrated circuit according to any example herein, in particular example 1, wherein the insulation material includes a build-up film.

Example 13 is a packaged integrated circuit according to any example herein, in particular example 1, wherein the insulation material includes a laminate material.

Example 14 is a packaged integrated circuit according to any example herein, in particular example 1, wherein the package substrate is a flipped routable lead frame.

Example 15 is a packaged integrated circuit including: a package substrate including: pins; a first metal layer on the pins; a second metal layer on the first metal layer; vias on the second metal layer; an insulation material covering the pins, the first metal layer, the second metal layer, and the vias, and exposing surfaces of the pins and the vias; a semiconductor die on the package substrate, the semiconductor die having a surface opposing the second metal layer; metal posts coupled between the semiconductor die and the exposed surfaces of the vias; and a mold compound covering the semiconductor die and the metal posts, in which the surface is separated from the second metal layer by the insulation material and the mold compound.

Example 16 is a packaged integrated circuit according to any example herein, in particular example 15, wherein the first metal layer has a first winding of a transformer, and wherein the second metal layer includes a second winding of the transformer.

Example 17 is a packaged integrated circuit according to any example herein, in particular example 16, wherein the transformer is a first transformer, wherein the package substrate includes a second transformer having a first winding on the first metal layer and a second winding on the second metal layer.

Example 18 is a packaged integrated circuit according to any example herein, in particular example 17, wherein portions of the first and second windings of the second transformer are within footprints of the first and second windings of the first transformer.

Example 19 is a packaged integrated circuit according to any example herein, in particular example 15, wherein the semiconductor die is a first semiconductor die, wherein the metal posts are a first set of metal posts, wherein the vias are a first set of vias, wherein the package integrated circuit includes a second semiconductor die on the package substrate, the second semiconductor die having a surface opposing the second metal layer, wherein the package substrate includes a second set of vias on the first metal layer, wherein the package integrated circuit includes a second set of metal posts coupled between the second semiconductor die and exposed surface of the second set of vias.

Example 20 is a method of fabricating a packaged integrated circuit, comprising: flipping a package substrate having a first metal layer, a second metal layer below the first metal layer, a third metal layer below the second metal layer, first vias coupled between the first metal layer and the second metal layer, second vias coupled between the second metal layer and the third metal layer, and third vias below the third metal layer, in which the first metal layers include pins; forming first metal posts on exposed surfaces of a first subset of the third vias; forming second metal posts on exposed surfaces of a second subset of the third vias; mounting a first semiconductor die on the first metal posts; mounting a second semiconductor die on the second metal posts; and covering the first and second semiconductor dies and the first and second metal posts with a mold compound.

Example 21 is a method according to any example herein, in particular example 20 further includes covering the first, second, and third metal layers and the first, second, and third vias with an insulation material.

Example 22 is a method according to any example herein, in particular example 21 further includes exposing surfaces of the pins and the third vias.

Example 23 is a method according to any example herein, in particular example 21, wherein the second metal layer includes a first winding of a transformer, wherein the third metal layer includes a second winding of the transformer, wherein the first semiconductor die has a first surface opposing the second winding, the second semiconductor die has a second surface opposing the second winding, the method further includes: separating the first surface and the second winding by the insulation material and the mold compound; and separating the second surface and the second winding by the insulation material and the mold compound.

Example 24 is a method according to any example herein, in particular example 23 further includes: coupling the first semiconductor die to the second winding via the first subset of the third vias; and coupling the second semiconductor die to the first winding via the second subset of the third vias and a subset of the second vias, wherein the first semiconductor die and the second winding are part of a first voltage domain; and wherein the second semiconductor die and the first winding are part of a second voltage domain.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In the description and in the claims, the terms “including” and “having” and variants thereof are intended to be inclusive in a manner similar to the term “comprising” unless otherwise noted. In addition, the terms “couple,” “coupled,” or “couples” means an indirect or direct electrical or mechanical connection.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics, or semiconductor component.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN), or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit

and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately,” or “substantially” preceding a parameter means being within +/−10 percent of that parameter or, if the parameter is zero, a reasonable range of values around zero.

What is claimed is:

1. A packaged integrated circuit comprising:
a package substrate including:
a first metal layer, a second metal layer on the first metal layer, a third metal layer on the second metal layer, first vias coupled between the first metal layer and the second metal layer, second vias coupled between the second metal layer and the third metal layer, and third vias on the third metal layer, in which the first metal layer include pins, the second metal layer includes a first winding of a transformer, and the third metal layer includes a second winding of the transformer; and
an insulation material covering the first, second, and third metal layers and the first, second, and third vias, and exposing surfaces of the pins and the third vias;
a first semiconductor die on the package substrate;
a second semiconductor die on the package substrate;
first metal posts coupled between the first semiconductor die and the exposed surfaces of a first subset of the third vias;
second metal posts coupled between the second semiconductor die and the exposed surfaces of a second subset of the third vias; and
a mold compound covering the first and second semiconductor dies and the first and second metal posts.

2. The packaged integrated circuit of claim 1, wherein the first semiconductor die has a first surface opposing the second winding, the second semiconductor die has a second surface opposing the second winding, the first surface and the second winding is separated by the insulation material and the mold compound, and the second surface and the second winding is separated by the insulation material and the mold compound.

3. The packaged integrated circuit of claim 2, wherein the first semiconductor die is coupled to the second winding via the first subset of the third vias, and the second semiconductor die is coupled to the first winding via the second subset of the third vias and a subset of the second vias;
wherein the first semiconductor die and the second winding are part of a first voltage domain; and
wherein the second semiconductor die and the first winding are part of a second voltage domain.

4. The packaged integrated circuit of claim 1, wherein the first winding includes a first coil portion, a second coil portion, and a first straight portion coupled between the first and second coil portions, the first straight portion being below the second semiconductor die; and
wherein the second winding includes a third coil portion, a fourth coil portion, and a second straight portion coupled between the third and fourth coil portions, the second straight portion being below the first semiconductor die.

5. The packaged integrated circuit of claim 4, wherein the first coil portion has a first end coupled to a first one of the second vias and a first one of the third vias, and the second coil portion has a second end coupled to a second one of the second vias and a second one of the third vias; and
wherein the third coil portion has a third end coupled to a third one of the third vias, and the fourth coil portion has a fourth end coupled to a fourth one of the third vias.

6. The packaged integrated circuit of claim 4, wherein the first coil portion overlaps with the third coil portion, and the second coil portion overlaps with the fourth coil portion.

7. The packaged integrated circuit of claim 4, wherein the first coil portion, the second coil portion, and the first straight portion form a first figure-of-B topology, and the third coil portion, the fourth coil portion, and the second straight portion form a second figure-of-B topology.

8. The packaged integrated circuit of claim 4, wherein the transformer is a first transformer, the second metal layer includes a first winding of a second transformer, and the third metal layer includes a second winding of the second transformer;
wherein the second winding of the second transformer includes a fifth coil portion and a sixth coil portion; and
wherein the first winding of the second transformer includes a seventh coil portion and an eighth coil portion.

9. The packaged integrated circuit of claim 8, wherein the fifth and seventh coil portions are within a footprint of the first and third coil portions; and
wherein the sixth and eighth coil portions are within a footprint of the second and fourth coil portions.

10. The packaged integrated circuit of claim 8, wherein the fifth, sixth, seventh, and eighth coil portions are within a footprint of the first and third coil portions.

11. The packaged integrated circuit of claim 10, wherein the second metal layer includes a first winding of a third transformer, and the third metal layer includes a second winding of the third transformer, and wherein the third transformer is within the footprint of the second and fourth coil portions.

12. The packaged integrated circuit of claim 1, wherein the insulation material includes a build-up film.

13. The packaged integrated circuit of claim 1, wherein the insulation material includes a laminate material.

14. The packaged integrated circuit of claim 1, wherein the package substrate is a flipped routable lead frame.

15. A packaged integrated circuit including:
a package substrate including:
pins;
a first metal layer on the pins;
a second metal layer on the first metal layer;
vias on the second metal layer;
an insulation material covering the pins, the first metal layer, the second metal layer, and the vias, and exposing surfaces of the pins and the vias;
a semiconductor die on the package substrate, the semiconductor die having a surface opposing the second metal layer;
metal posts coupled between the semiconductor die and the exposed surfaces of the vias; and
a mold compound covering the semiconductor die and the metal posts, in which the surface is separated from the second metal layer by the insulation material and the mold compound.

16. The packaged integrated circuit of claim 15, wherein the first metal layer has a first winding of a transformer, and wherein the second metal layer includes a second winding of the transformer.

17. The packaged integrated circuit of claim 16, wherein the transformer is a first transformer, wherein the package substrate includes a second transformer having a first winding on the first metal layer and a second winding on the second metal layer.

18. The packaged integrated circuit of claim 17, wherein portions of the first and second windings of the second transformer are within footprints of the first and second windings of the first transformer.

19. The packaged integrated circuit of claim 15, wherein the semiconductor die is a first semiconductor die, wherein the metal posts are a first set of metal posts, wherein the vias are a first set of vias, wherein the package integrated circuit includes a second semiconductor die on the package substrate, the second semiconductor die having a surface opposing the second metal layer, wherein the package substrate includes a second set of vias on the first metal layer, wherein the package integrated circuit includes a second set of metal posts coupled between the second semiconductor die and exposed surface of the second set of vias.

20. A method of fabricating a packaged integrated circuit, comprising:
flipping a package substrate having a first metal layer, a second metal layer below the first metal layer, a third metal layer below the second metal layer, first vias coupled between the first metal layer and the second metal layer, second vias coupled between the second metal layer and the third metal layer, and third vias below the third metal layer, in which the first metal layers include pins;
forming first metal posts on exposed surfaces of a first subset of the third vias;
forming second metal posts on exposed surfaces of a second subset of the third vias;
mounting a first semiconductor die on the first metal posts;
mounting a second semiconductor die on the second metal posts; and
covering the first and second semiconductor dies and the first and second metal posts with a mold compound.

21. The method of claim 20, further comprising covering the first, second, and third metal layers and the first, second, and third vias with an insulation material.

22. The method of claim 21, further comprising exposing surfaces of the pins and the third vias.

23. The method of claim 21, wherein the second metal layer includes a first winding of a transformer, wherein the third metal layer includes a second winding of the transformer, wherein the first semiconductor die has a first surface opposing the second winding, the second semiconductor die has a second surface opposing the second winding, the method further includes:
separating the first surface and the second winding by the insulation material and the mold compound; and
separating the second surface and the second winding by the insulation material and the mold compound.

24. The method of claim 23, further comprising:
coupling the first semiconductor die to the second winding via the first subset of the third vias; and
coupling the second semiconductor die to the first winding via the second subset of the third vias and a subset of the second vias, wherein the first semiconductor die and the second winding are part of a first voltage domain; and wherein the second semiconductor die and the first winding are part of a second voltage domain.
